(19) United States
(12) Patent Application Publication
(10) Pub. No.: US 2024/0424903 A1
(43) Pub. Date: Dec. 26, 2024

(54) THERMAL RUNWAY DETECTION AND MITIGATION SYSTEMS AND METHODS FOR BATTERY SYSTEMS OF ELECTRIFIED VEHICLES

(71) Applicant: FCA US LLC, Auburn Hills, MI (US)

(72) Inventors: Jinhua Li, Shanghai (CN); Zhenguan Chen, Shanghai (CN); Zhong Zheng, Shanhai (CN); Yang Xu, Shanghai (CN)

(21) Appl. No.: 18/337,766

(22) Filed: Jun. 20, 2023

(51) Int. Cl. B60L 3/00; G01R 31/3835; H01M 10/42

(52) U.S. Cl. CPC B60L 3/0046; G01R 31/3835; H01M 10/425; H01M 2010/4271; H01M 2220/20

(57) ABSTRACT

Thermal runaway detection and mitigation techniques for high voltage battery systems of electrified vehicles include a relay connected between two battery modules of the high voltage battery system and control logic for the relay, the control logic being configured to determine a voltage between the two battery modules, detect the thermal runaway event of the high voltage battery system based on a change in the voltage over a period, and open/close the relay in response to detecting the imminent thermal runaway event, wherein the detection of the thermal runaway event and the responsive opening of the relay prevent or mitigate potential thermal propagation outside of the high voltage battery system.

### FIELD

The present application generally relates to electrified vehicles and, more particularly, to thermal runaway detection and mitigation systems and methods for high voltage battery systems of electrified vehicles.

### BACKGROUND

Electrified vehicles (battery electric vehicles (BEVs), plug-in hybrid electric vehicles (PHEVs), etc.) include electric motor(s) configured to generate mechanical drive torque using electrical energy (e.g., current) provided by a high voltage battery system. “Thermal runaway” is potentially problematic situation for a battery systems. Thermal runaway refers to the scenario when the heat generated within a battery system exceeds the amount of heat that is dissipated to its surroundings, which could severely damage the battery system and could potentially thermally propagate outside of the battery system and cause other component damage and/or a thermal event. One solution is to implement a physical fuse or busbar connection between the battery modules (e.g., in a traction battery management unit, or TBMU), but this solution is potentially not very robust as it requires replacement after malfunction. Accordingly, while such conventional electrified vehicle battery management techniques do work well for their intended purpose, there exists an opportunity for improvement in the relevant art.

### SUMMARY

According to one example aspect of the invention, a battery management system (BMS) for detection and mitigation of a thermal runaway event of a high voltage battery system configured to power one or more electric traction motors of an electrified vehicle is presented. In one exemplary implementation, the BMS comprises a relay connected between two battery modules of the high voltage battery system and control logic for the relay, the control logic configured to determine a voltage between the two battery modules, detect the thermal runaway event of the high voltage battery system based on a change in the voltage over a period, and open/close the relay in response to detecting the imminent thermal runaway event, wherein the detection of the thermal runaway event and the responsive opening of the relay prevent or mitigate potential thermal propagation outside of the high voltage battery system.

In some implementations, the control logic is also configured to open the relay (i) when the electrified vehicle is asleep to save energy and (ii) during maintenance servicing to protect a service technician from high voltage conditions. In some implementations, the control logic is further configured to perform a diagnostic of the relay to verify that it is functioning properly to improve robustness of the BMS. In some implementations, the control logic is configured to perform the diagnostic of the relay as: the relay is stuck closed when the relay should be open and (i) a difference between (a) the voltage and (b) a sum of cell voltages of a set of battery cells in one of the battery modules is less than or equal to (ii) a threshold, and the relay is stuck open when the relay should be closed and (i) the difference between (a) the voltage and (b) the sum of cell voltages of the set of battery cells in one of the battery modules is less than or equal to (ii) the threshold.

In some implementations, the threshold is equal to a sum of voltage tolerances of the battery modules and a voltage tolerance of the relay voltage-side. In some implementations, the BMS further comprises a voltage sensor configured to measure the voltage between the two battery modules on the relay voltage-side. In some implementations, the relay is a solenoid-controlled switch. In some implementations, the electrified vehicle does not include a manual service disconnect (MSD) associated with the high voltage battery system.

According to another example aspect of the invention, a method for detection and mitigation of a thermal runaway event of a high voltage battery system configured to power one or more electric traction motors of an electrified vehicle is presented. In one exemplary implementation, the method comprises providing a relay connected between two battery modules of the high voltage battery system, providing control logic for the relay, determining, by the control logic, a voltage between the two battery modules, detecting, by the control logic, the thermal runaway event of the high voltage battery system based on a change in the voltage over a period, and opening/closing, by the control logic, the relay in response to detecting the imminent thermal runaway event, wherein the detection of the thermal runaway event and the responsive opening of the relay prevent or mitigate potential thermal propagation outside of the high voltage battery system.

In some implementations, the method further comprises opening, by the control logic, the relay (i) when the electrified vehicle is asleep to save energy and (ii) during maintenance servicing to protect a service technician from high voltage conditions. In some implementations, the method further comprises performing, by the control logic, a diagnostic of the relay to verify that it is functioning properly to improve robustness of the BMS. In some implementations, the control logic is configured to perform the diagnostic of the relay as: the relay is stuck closed when the relay should be open and (i) a difference between (a) the voltage and (b) a sum of cell voltages of a set of battery cells in one of the battery modules is less than or equal to (ii) a threshold, and the relay is stuck open when the relay should be closed and (i) the difference between (a) the voltage and (b) the sum of cell voltages of the set of battery cells in one of the battery modules is less than or equal to (ii) the threshold.

In some implementations, the threshold is equal to a sum of voltage tolerances of the battery modules and a voltage tolerance of the relay voltage-side. In some implementations, the method further comprises further comprising providing a voltage sensor on the relay voltage-side, the voltage sensor being configured to measure the voltage between the two battery modules. In some implementations, the relay is a solenoid-controlled switch. In some implementations, the electrified vehicle does not include an MSD associated with the high voltage battery system.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having a high voltage battery system and an example battery management system (BMS) for thermal runaway event detection and mitigation according to the principles of the present application;

FIGS. 2A-2B are circuit diagrams of an example configurations of the BMS for thermal runaway event detection and mitigation according to the principles of the present application; and

FIG. 3 is a flow diagram of an example thermal runaway event detection and mitigation method for a high voltage battery system configured to power one or more electric traction motors of an electrified vehicle according to the principles of the present application.

### DESCRIPTION

As previously discussed, “thermal runaway” refers to the scenario when the heat generated within a battery system exceeds the amount of heat that is dissipated to its surroundings, which could severely damage the battery system and could potentially thermally propagate outside of the battery system and cause other component damage or thermal events. One conventional solution to this problem for high voltage battery systems of electrified vehicles is to implement a physical fuse or busbar connection between the battery modules (e.g., in a traction battery management unit, or TBMU), but this solution is not very robust as it requires replacement after malfunction. Another conventional solution is a manual service disconnect (MSD) that detects a thermal runaway event occurring and disconnects the high voltage battery system, but this is a rather costly solution. Thus, while such conventional electrified vehicle battery management techniques do work well for their intended purpose, there exists an opportunity for improvement in the relevant art.

Accordingly, improved thermal runaway event detection and mitigation systems and methods for high voltage battery systems of an electrified vehicle as presented herein. These systems and methods add an additional relay between battery modules of a high voltage battery system and implement new control logic for a battery management system (BMS) to quickly detect a voltage fluctuation indicative of a thermal runaway event. By increasing a time gap from the detection of this voltage fluctuation by the BMS and the beginning of the thermal runaway event, there is more time to take corrective action on top of disconnecting the battery modules/system, such as generating and transmitting a controller area network (CAN) alarm and warning an operator of the electrified vehicle. These techniques are also very robust and less expensive than the conventional MSD solution.

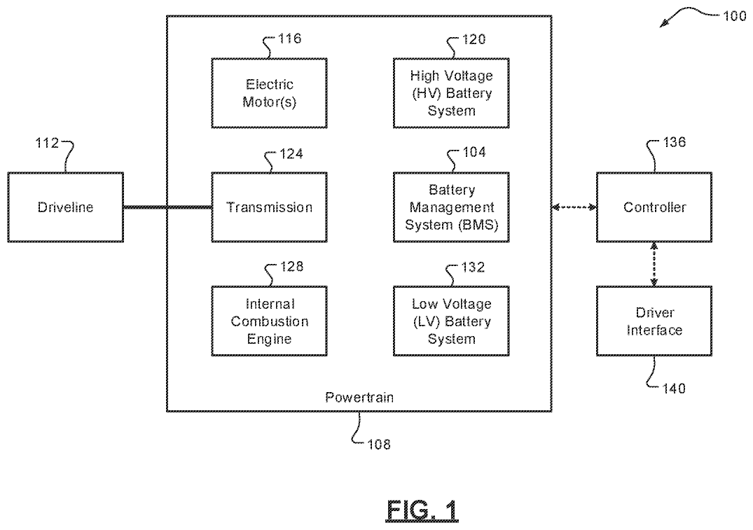

Referring now to FIG. 1, a functional block diagram of an electrified vehicle 100 having an example BMS 104 according to the principles of the present application is illustrated. The electrified vehicle 100 could be any suitable type of electrified vehicle, including, but not limited to, a battery electric vehicle (BEV) and a plug-in hybrid electric vehicle (PHEV). The electrified vehicle 100 comprises an electrified powertrain 108 configured to generate and transfer drive torque to a driveline 112 for vehicle propulsion. The electrified powertrain 108 includes one or more electric traction motors 116 each configured to generate mechanical drive torque using energy (e.g., electrical current) supplied by a high voltage battery system 120. For example, an inverter (not shown) could be used to convert the direct current (DC) from the high voltage battery system 120 to three-phase alternating current (AC) to power the electric traction motor(s) 116. A transmission 124 (e.g., an automatic transmission) is configured to transfer the drive torque from the electrified powertrain 108 to the driveline 112.

The electrified powertrain 108 also includes an optional internal combustion engine 128 configured to combust a mixture of air and fuel (gasoline, diesel, etc.) to generate mechanical torque for vehicle propulsion and/or conversion to electrical energy, such as for battery system recharging. A low voltage battery system 132 (e.g., a 12 volt (V) battery) is configured to power low voltage components and accessory loads of the electrified vehicle 100. A controller 136 is configured to control the electrified powertrain 108, including controlling the electrified powertrain to generate an amount of drive torque to satisfy a torque request provided by a driver/operator via a driver interface 140 (e.g., an accelerator pedal). The battery management system 104 could be part of or integrated with the controller 136 or could be its own separate or standalone system (e.g., with its own controller, such as a TBMU). The operation of the BMS 104 for thermal runaway event detection and mitigation and some examples of its circuit configurations per some implementations of the present application will now be shown and described in greater detail.

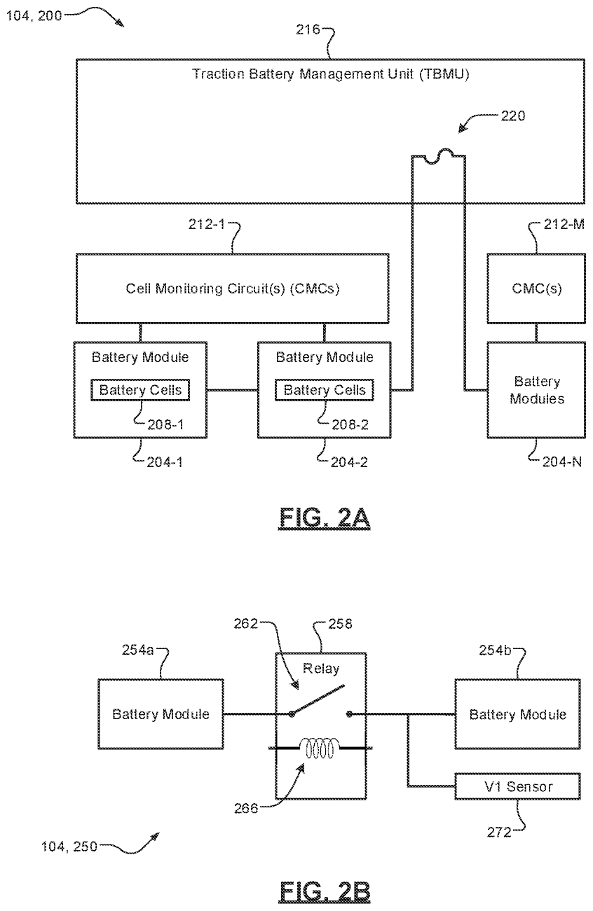

Referring now to FIGS. 2A-2B and with continued reference to FIG. 1, circuit diagrams of an example configuration 200, 250 of the BMS 104 according to the principles of the present application are illustrated. In FIG. 2A, an example circuit configuration 200 for the BMS 104 is illustrated. The high voltage battery system 120 comprises a plurality of battery modules 204-1 . . . 204-N (N being an integer greater than one; collectively, “battery modules 204”) and each battery module 204 comprises a respective set of one or more battery cells 208-1 . . . 208-N. One non-limiting example of the battery cells 208 is low voltage lithium ion (Li-ion) battery cells. The battery modules 204 are connected in series and are monitored by a set of one or more cell monitoring circuits (CMCs) 212-1 . . . 212-M (M being an integer greater than or equal to one; collectively, “CMCs 212”). A TBMU 216 is configured to oversee the CMCs 212 and the operation of the high voltage battery pack 120 as a whole. The TBMI 216, for example, could include a physical fuse or busbar 220, which is one of the less robust conventional solutions previously described herein.

In FIG. 2B, another circuit diagram of an example configuration 250 of a sub-portion of the BMS 104 is illustrated. As shown, there are two neighboring battery modules 254a, 254b connected in series with each other and also with a relay 258 according to the principles of the present application therebetween. In one exemplary configuration, the relay 258 is a solenoid-controlled relay (a switch 262 actuated opened/closed by a solenoid 266) as shown, but it will be appreciated that other electrically or electro-mechanically actuated relays could be utilized. A voltage sensor (V1 Sensor) 272 is configured to measure/monitor a voltage on a voltage-side of the relay 258 (i.e., proximate to battery module 254b). Control logic for the relay is implemented in the BMS 104 or the controller 136 of the electrified vehicle 100. The control logic is configured to perform a diagnostic of the relay 258 to ensure it is functioning properly (i.e., not malfunctioning) and also to operate the relay 258 to mitigate a detected thermal runaway event (e.g., based on a change or fluctuation of the voltage V1 over a period).

The control logic could also be configured to open the relay 258 (i) when the electrified vehicle 100 is asleep to save energy and (ii) during maintenance servicing to protect a service technician from high voltage conditions. In one example implementation, the control logic is configured to perform the diagnostic of the relay 258 to verify that it is functioning properly to improve robustness of the BMS as follows: (1) the relay 258 is stuck closed when the relay 258 should be open and (i) a difference between (a) the voltage V1 and (b) a sum of cell voltages of a set of battery cells 208 in battery module 254a is less than or equal to (ii) a threshold, and (2) the relay 258 is stuck open when the relay 258 should be closed and (i) the difference between (a) the voltage V1 and (b) the sum of cell voltages of the set of battery cells 208 in battery module 254a is less than or equal to (ii) the threshold. In one exemplary implementation, the threshold is equal to a sum of voltage tolerances of the battery modules 245a, 254b and a voltage tolerance of the relay voltage-side V1 (e.g., as measured by sensor 272). In addition to improved robustness, this proposed thermal runaway detection and mitigation system is does not include or require an MSD associated with the high voltage battery system 120, thereby saving costs and complexity.

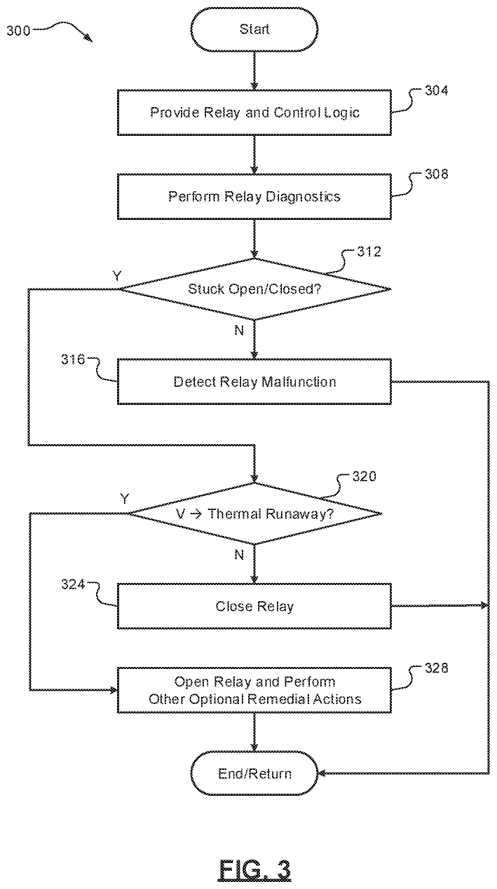

Referring now to FIG. 3 and with continued reference to FIGS. 1 and 2A-2B, a flow diagram of an example thermal runaway event detection and mitigation method 300 for a high voltage battery system configured to power one or more electric traction motors of an electrified vehicle according to the principles of the present application is illustrated. While the electrified vehicle 100, its components, and the example circuit configurations 200, 250 are specifically references for descriptive/illustrative purposes, it will be appreciated that the method 300 could be applicable to any suitable electrified vehicle. At 304, the relay 258 and its corresponding control logic (e.g., in the BMS 104) are provided. At 308, the control logic performs diagnostics of the relay 258, such as the diagnostics as previously described above herein. At 312, the control logic determines whether the relay 258 is stuck open or closed as a result of the diagnostics.

When true, the method 300 proceeds to 316 where the control logic detects a malfunction of the relay 258 (e.g., sets an appropriate malfunction code/flag) and the method 300 ends or returns to 304. When false, the method 300 proceeds to 320. At 320, the control logic determines whether the voltage (e.g., as measured by V1 sensor 272) has a pattern or fluctuation indicative of a thermal runaway event. When false, the method 300 proceeds to 324 where the control logic closes the relay 258 (e.g., or keeps the relay 258 closed) and the method 300 ends or returns to 304. When true, the method 300 proceeds to 328. At 328, the control logic opens the relay 258 to mitigate the thermal runaway event. At 328 (or a subsequent 332), the control logic could also take other remedial action, such as generating a CAN alarm to notify other components of the electrified vehicle 100 about the detected thermal runaway event and/or generate and provide a warning/malfunction message to an operator of the electrified vehicle 100. The method 300 then ends or returns to 304 for one or more additional cycles.

It will be appreciated that the term “controller” as used herein refers to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A battery management system (BMS) for detection and mitigation of a thermal runaway event of a high voltage battery system configured to power one or more electric traction motors of an electrified vehicle, the BMS comprising:
a relay connected between two battery modules of the high voltage battery system; and
control logic for the relay, the control logic configured to:
determine a voltage between the two battery modules;
detect an imminent thermal runaway event of the high voltage battery system based on a change in the voltage over a period; and
open/close the relay in response to detecting the imminent thermal runaway event,
wherein the detection of the imminent thermal runaway event and the responsive opening of the relay prevents or mitigates thermal propagation outside of the high voltage battery system.

2. The BMS of claim 1, wherein the control logic is also configured to open the relay (i) when the electrified vehicle is asleep to save energy and (ii) during maintenance servicing to protect a service technician from high voltage conditions.

3. The BMS of claim 1, wherein the control logic is further configured to perform a diagnostic of the relay to verify that it is functioning properly to improve robustness of the BMS.

4. The BMS of claim 3, wherein the control logic is configured to perform the diagnostic of the relay as:
the relay is stuck closed when the relay should be open and (i) a difference between (a) the voltage and (b) a sum of cell voltages of a set of battery cells in one of the battery modules is less than or equal to (ii) a threshold; and
the relay is stuck open when the relay should be closed and (i) the difference between (a) the voltage and (b) the sum of cell voltages of the set of battery cells in one of the battery modules is less than or equal to (ii) the threshold.

5. The BMS of claim 4, wherein the threshold is equal to a sum of voltage tolerances of the battery modules and a voltage tolerance of the relay voltage-side.

6. The BMS of claim 5, further comprising a voltage sensor configured to measure the voltage between the two battery modules on the relay voltage-side.

7. The BMS of claim 1, wherein the relay is a solenoid-controlled switch.

8. The BMS of claim 1, wherein the electrified vehicle does not include a manual service disconnect (MSD) associated with the high voltage battery system.

9. A method for detection and mitigation of a thermal runaway event of a high voltage battery system configured to power one or more electric traction motors of an electrified vehicle, the method comprising:
providing a relay connected between two battery modules of the high voltage battery system;
providing control logic for the relay;
determining, by the control logic, a voltage between the two battery modules;
detecting, by the control logic, an imminent thermal runaway event of the high voltage battery system based on a change in the voltage over a period; and
opening/closing, by the control logic, the relay in response to detecting the imminent thermal runaway event,
wherein the detection of the imminent thermal runaway event and the responsive opening of the relay prevent or mitigate thermal propagation outside of the high voltage battery system.

10. The method of claim 9, further comprising opening, by the control logic, the relay (i) when the electrified vehicle is asleep to save energy and (ii) during maintenance servicing to protect a service technician from high voltage conditions.

11. The method of claim 9, further comprising performing, by the control logic, a diagnostic of the relay to verify that it is functioning properly to improve robustness of the BMS.

12. The method of claim 11, wherein the control logic is configured to perform the diagnostic of the relay as:
the relay is stuck closed when the relay should be open and (i) a difference between (a) the voltage and (b) a sum of cell voltages of a set of battery cells in one of the battery modules is less than or equal to (ii) a threshold; and
the relay is stuck open when the relay should be closed and (i) the difference between (a) the voltage and (b) the sum of cell voltages of the set of battery cells in one of the battery modules is less than or equal to (ii) the threshold.

13. The method of claim 12, wherein the threshold is equal to a sum of voltage tolerances of the battery modules and a voltage tolerance of the relay voltage-side.

14. The method of claim 13, further comprising providing a voltage sensor on the relay voltage-side, the voltage sensor being configured to measure the voltage between the two battery modules.

15. The method of claim 9, wherein the relay is a solenoid-controlled switch.

16. The method of claim 9, wherein the electrified vehicle does not include a manual service disconnect (MSD) associated with the high voltage battery system.
